(19) United States
(12) Patent Application Publication
(10) Pub. No.: US 2025/0314706 A1
(43) Pub. Date: Oct. 9, 2025

(54) THERMAL RUN-AWAY MONITORING OF BATTERY CELLS

(71) Applicant: The Boeing Company, Arlington, VA (US)

(72) Inventors: Dustin P. Greene, Aledo, TX (US); John M. Holder, Plano, TX (US)

(21) Appl. No.: 18/630,680

(22) Filed: Apr. 9, 2024

(51) Int. Cl. G01R 31/392; G01R 31/367; G01R 31/3835; G01R 31/396; H01M 10/48; H01M 50/249; H02J 7/00

(52) U.S. Cl. CPC G01R 31/392; G01R 31/367; G01R 31/3835; G01R 31/396; H01M 10/484; H01M 10/486; H02J 7/0048; H01M 50/249

(57) ABSTRACT

Thermal run-away monitoring of battery cells during charging is described. Thermal run-away monitoring of a battery cell includes charging the battery cell; measuring concurrently a state of charge of the battery cell, and at least one of voltage and electrolyte consumption while charging the battery cell; recording a set of data for the battery cell, each member of the set of data comprising the state of charge of the battery cell, and at least one of voltage and electrolyte consumption; comparing the set of data for the battery cell to a historical database of measurements from other battery cells characteristic of a type associated with the battery cell; and predicting a probability of thermal run-away of the battery cell based on comparison of set of data for the battery cell to the historical database of measurements from other battery cells characteristic of the type associated with the battery cell.

### BACKGROUND INFORMATION

### 1. Field

The present disclosure relates generally to battery cell thermal run-away monitoring apparatus and battery cell thermal run-away monitoring methodologies, and more specifically to a battery cell thermal run-away monitoring tool for battery cells and associated methodologies.

### 2. Background

Vehicles are dependent on their batteries. Batteries deteriorate over time, require maintenance, and can be subject to thermal run-away. While there can be many causes of thermal run-away, typically thermal run-away is started by just one cell in the battery.

When a battery cell runs (experiences thermal run-away), it typically combusts into a fire damaging itself and the battery cells around it. This usually results damaging, or at least degrading, the entire battery into an unusable state.

The only previous approach to managing thermal run-away of battery cells is monitoring battery temperature. However, a major limitation of this approach is that it only identifies that a cell is running too hot, but not which cell(s) of the battery. Another major limitation of this approach is that it is triggered only after it is too late to avoid a thermal run-away event.

However, a significant drawback to this previous approach is that before every shut-off some corrosive electrolyte is drawn into the vacuum system through the orifice. The problems inherent with this previous approach are related to corrosion and inconsistency. Because a vacuum is used to make contact with rising electrolyte, corrosive potassium hydroxide electrolyte is introduced to the internals of the system. This causes false pressure reading over time leading to inconsistency. Eventually, corrosion degrades the vacuum system, especially the conduit defining the orifice, leading to absence of precision and even contamination of the electrolyte. Ultimately, systems that implement this previous approach inevitably fail before the end of their theoretical life cycle. Another significant drawback to this contact approach is cross-contamination of electrolyte between cells.

Therefore, it would be desirable to have a thermal runaway monitoring tool for battery cells, as well as methods of using that tool that take into account at least some of the issues discussed above, as well as other possible issues.

### SUMMARY

There is a need for the following embodiments of the present disclosure. Of course, the present disclosure is not limited to these embodiments.

Embodiments of the present disclosure can identify a battery cell (e.g., NiCd) that has entered thermal run-away by determining that sensor data has entered an area that could lead to a thermal run-away. The variables looked at would be cell voltages at various states of charge and/or electrolyte (e.g., water) consumption during charge.

An embodiment of the present disclosure provides a method of thermal run-away monitoring of a battery cell, comprising: charging the battery cell; measuring concurrently a state of charge of the battery cell, and at least one of voltage and electrolyte consumption while charging the battery cell; recording a set of data for the battery cell, each member of the set of data comprising the state of charge of the battery cell, and at least one of voltage and electrolyte consumption; comparing the set of data for the battery cell to a historical database of measurements from other battery cells characteristic of a type associated with the battery cell; and predicting a probability of thermal run-away of the battery cell based on comparison of set of data for the battery cell to the historical database of measurements from other battery cells characteristic of the type associated with the battery cell.

Another embodiment of the present disclosure provides an apparatus for thermal run-away monitoring of a battery cell, comprising: a sensor system measuring concurrently a state of charge of the battery cell; and at least one of voltage and electrolyte consumption; a memory recording a set of data for the battery cell, each member of the set of data comprising at least one of voltage and electrolyte consumption and the state of charge of the battery cell; a pattern recognition system comparing the set of data for the battery cell to a historical database of measurements from other battery cells characteristic of a type associated with the battery cell; and a prediction system predicting a probability of thermal run-away of the battery cell based on comparison of the set of data for the battery cell to the historical database of measurements from other battery cells characteristic of the type associated with the battery cell. The sensor can optionally be configured to measure a voltage between an anode of the battery cell and a cathode of the battery cell, where the voltage is measured at a plurality of states of charge.

Another embodiment of the present disclosure provides a method of thermal run-away monitoring of a battery cell, comprising: charging the battery cell; measuring concurrently at least one of voltage and electrolyte consumption, and a state of charge while charging the battery cell; recording a set of data for the battery cell, each member of the set of data comprising at least one of voltage and electrolyte consumption, and the state of charge of the battery cell; comparing the set of data for the battery cell to a historical database of measurements from other battery cells characteristic of a type associated with the battery cell; predicting a probability of thermal run-away of the battery cell based on comparison of set of data for the battery cell to the historical database of measurements from other battery cells characteristic of the type associated with the battery cell; removing the battery cell from a battery in response to the probability being greater than a predetermined threshold; and replacing the battery cell with another battery cell.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is an illustration of a block diagram of an apparatus comprising a thermal run-away monitoring system for battery cells in accordance with an illustrative embodiment;

FIG. 2 is an illustration of a flowchart of a process for thermal run-away monitoring of a battery cell in accordance with an illustrative embodiment;

FIG. 3 is an illustration of a flowchart of a process for removing a battery cell from a battery and replacing with another battery cell in accordance with an illustrative embodiment;

FIG. 4 is an illustration of a flowchart of a process for measuring voltage of a battery cell in accordance with an illustrative embodiment;

FIG. 5 is an illustration of a flowchart of a process for measuring electrolyte consumption by a battery cell in accordance with an illustrative embodiment;

FIG. 6 is an illustration of an aircraft manufacturing and service method in a form of a block diagram in accordance with an illustrative embodiment; and

FIG. 7 is an illustration of an aircraft in the form of a block diagram in which an illustrative embodiment may be implemented.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well-known materials, techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

The disclosure of this application is technically related to co-pending U.S. Ser. No. 18/601,855 (attorney docket number 24-0005-US-NP), filed Mar. 11, 2024, the entire contents of which are hereby expressly incorporated by reference for all purposes. U.S. Ser. No. 18/601,855 is incorporated herein by reference because it discloses an apparatus that is useful for positioning a battery to be serviced at an origin and then pulling individual battery cells from that battery using a gantry. The disclosure of this application is technically related to co-pending U.S. Ser. No. 18/601,974 (attorney docket number 24-0009-US-NP), filed Mar. 11, 2024, the entire contents of which are hereby expressly incorporated by reference for all purposes. U.S. Ser. No. 18/601,974 is incorporated herein by reference because it disclosed an apparatus that is useful for non-contact electrolyte sensor measurements within battery cells.

Embodiments of this disclosure can identify a battery cell that is likely to experience thermal run-away early enough to remove it from the battery. This saves the rest of the cells from damage.

Embodiments of this disclosure can use a historical database to identify thermal run-away early while the only other solution is to identify a temperature excursion when it is too late to mitigate or salvage. The historical database is an ever growing data log that compares data to add identifiers of a run-away. It is a significant commercial advantage of embodiments of this disclosure that the identification of the battery cell that is probably going to thermal run-away happens before the run-away. Consequently, the battery cell that is probably going to thermal run-away can be replaced or at least removed before damage happens.

Embodiments of this disclosure can be used by skilled, semiskilled and non-skilled workers servicing NiCad Batteries. Embodiments of this disclosure can be used by workers in any country. Embodiments of this disclosure can be used to service an aircraft battery, an automotive battery, a submersible battery, or any other kind of battery that includes rechargeable battery cells. Embodiments of this disclosure can be integrated into an aircraft battery servicing machine.

Embodiments of this disclosure significantly reduce the probability and risk of damage to surrounding battery cells, especially nearest neighbors. Embodiments of this disclosure can be utilized to create a revenue steam because battery maintenance customers can appreciate the value generated by reducing the probability and risk of damage to surrounding battery cells, entire batteries, and surrounding equipment.

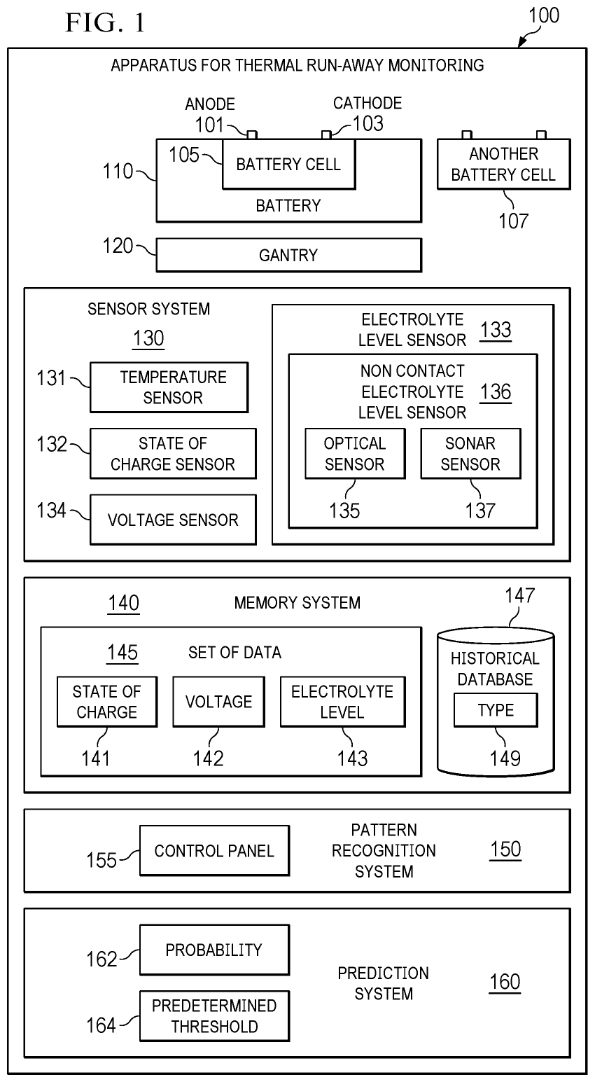

Turning now to FIG. 1, an illustration of a block diagram of apparatus for thermal runaway monitoring is depicted in accordance with an illustrative embodiment. The apparatus for thermal runaway monitoring 100 includes battery 110. Battery 110 includes battery cell 105. Battery cell 105 includes anode 101 and cathode 103. A gantry 120 is located above battery cell 105.

The apparatus for thermal runaway monitoring 100 includes a sensor system 130. The sensor system 130 includes a temperature sensor 131. The temperature sensor 131 can be configured to measure a temperature proximate and/or adjacent the battery cell 105. The sensor system 130 includes a state of charge sensor 132. The sensor system 130 includes A voltage sensor 134. The sensor system 130 includes an electrolyte level sensor 133. The electrolyte level sensor 133 can include a non-contact electrolyte level sensor 136. The non-contact electrolyte level sensor 136 can include an optical sensor 135 and/or a sonar sensor 137.

Apparatus for thermal runaway monitoring 100 includes a memory system 140. The memory system 140 includes a set of data 145. The set of data 145 includes state of charge data 141. The set of data 145 includes voltage data 142 and slash or electrolyte level data 143. The memory system 140 includes historical database 147. Historical database 147 can include type data 149.

Apparatus for thermal runaway monitoring 100 includes a pattern recognition system 150. The pattern recognition system 150 can include a control panel 155.

Apparatus for thermal runaway monitoring 100 includes prediction system 160. The prediction system 160 can include a predetermined threshold 164. The prediction system 160 can include a probability 162.

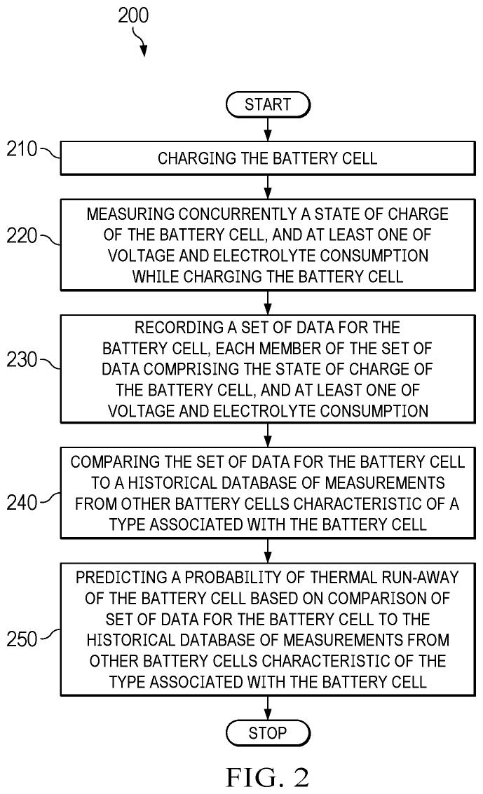

Referring to FIG. 2, a process for monitoring thermal run-away of a battery cell is shown. Block 210 includes charging the battery cell. Block 220 includes measuring concurrently the state of charge of the battery cell, and at least one of voltage and electrolyte consumption while charging the battery cell. Block 230 includes recording a set of data for the battery cell, each member of the set of data comprising the state of charge of the battery cell, and at least one of voltage and electrolyte consumption. Block 240 includes comparing the set of data for the battery cell to a historical database of measurements from other battery cells characteristic of a type associated with the battery cell. Block 250 includes predicting a probability of thermal run-away of the battery cell based on comparison of set of data for the battery cell to the historical database of measurements from other battery cells characteristic of the type associated with the battery cell.

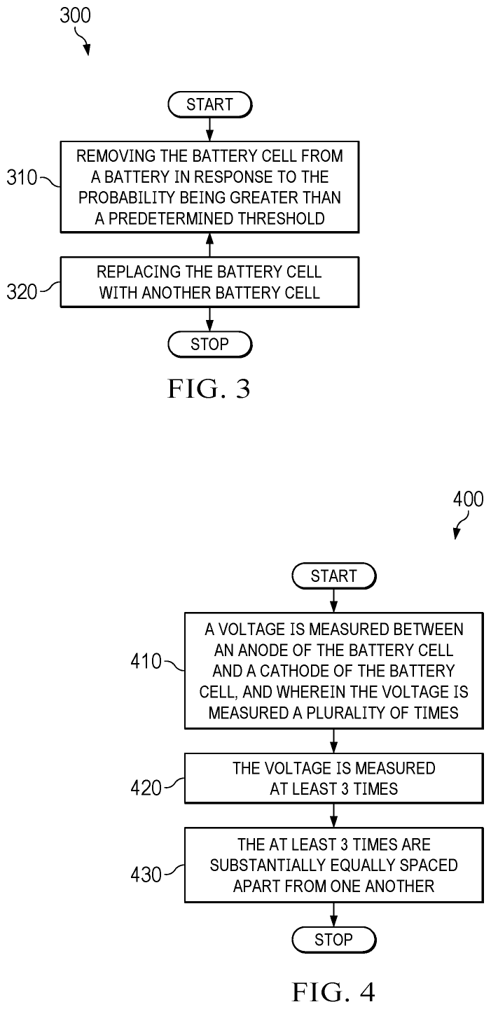

Referring to FIG. 3, an optional process for removing a battery cell from a battery and replacing with another battery cell is shown. Block 310 includes removing the battery cell from a battery in response to the probability being greater than a predetermined threshold. Block 320 includes replacing the battery cell with another battery cell.

Referring to FIG. 4, an optional process for measuring voltage of a battery cell is shown. Block 410 includes measuring voltage between an anode of the battery cell and a cathode of the battery cell, where the voltage is measured a plurality of times. Block 420 depicts an optional aspect of this optional process where the voltage is measured at least 3 times. Block 430 depicts an optional aspect of this optional process where the at least 3 times are substantially equally spaced apart temporally from one another.

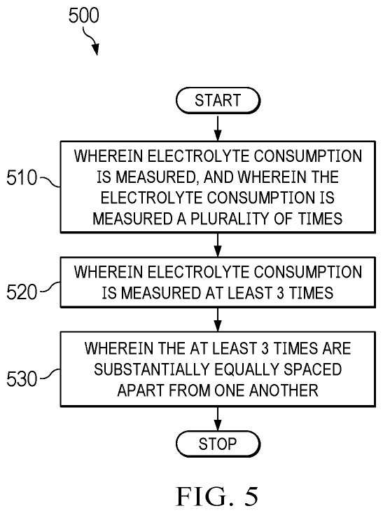

Referring to FIG. 5, an optional process for measuring electrolyte consumption by a battery cell is shown. Block 510 includes measuring electrolyte consumption, where the electrolyte consumption is measured a plurality of times. Block 520 depicts an optional aspect of this optional process where the electrolyte consumption is measured at least 3 times. Block 530 depicts an optional aspect of this optional process where the at least 3 times are substantially equally spaced apart temporally from one another

### EXAMPLES

Specific exemplary embodiments will now be further described by the following, nonlimiting examples which will serve to illustrate in some detail various features. The following examples are included to facilitate an understanding of ways in which embodiments of the present disclosure may be practiced. However, it should be appreciated that many changes can be made in the exemplary embodiments which are disclosed while still obtaining like or similar result without departing from the scope of embodiments of the present disclosure. Accordingly, the examples should not be construed as limiting the scope of the present disclosure.

Embodiments of this disclosure can include a thermal run-away monitoring algorithm. This Algorithm is meant to be a proprietary software that will be integrated into our Battery Servicing Machine. We have compiled 5 years of battery testing data that the software will compare current batteries against to determine if a cell will thermal run-away before it becomes hazardous or damages other costly components of the battery.

### Example 1

This exemplary algorithm looks at voltages of individual cells in real time during charging. It can create alarm flags that will alert the operator to check the cell indicated. It is looking for a percent of difference between said cell, the average over the battery, and the cells before and after it in series.

Next this exemplary algorithm monitors the change in voltage over a given time, which if a rapid increase or decrease is detected, the cell will be flagged.

Finally, it will compare water consumption between the cells. If a cell consumes a certain percentage more than the average of the other cells, it will be flagged.

The percentage comparison on both voltage and water, and time to voltage ratio will be variables that can be set by the operator. The interface will provide a check list for the operator to ensure the cell is bad as well defining scenarios that the cell could have a percent difference without being defective.

Sampling specifics can evolve as the system starts to gather live data. Data that currently exists in the historical database includes periodic checks during the charging process. The following is what portions of the above-described code can look like.
def flag_cells(cell_voltages):
   flagged_cells=[ ]
   for i in range (1, len(cell_voltages)−1):
      previous_voltage=cell_voltages[i−1]
      current_voltage=cell_voltages[i]
      next_voltage=cell_voltages[i+1]
      percentage_difference=abs(current_voltage−previous_voltage)/previous_voltage*100
      if percentage_difference>2:
         flagged_cells.append(i)
      percentage_difference_next=abs(next_voltage−current_voltage)/current_voltage*100
      if percentage_difference_next>2:
         flagged_cells.append(i+1)
   return flagged_cells
#Example usage:
all_cell_voltages=[3.5, 3.6, 3.8, 3.7, 3.9, 3.6, 3.5, 3.7, 3.6, 3.8, 3.9, 4.0, 4.1, 4.2, 4.1, 4.0, 4.2, 4.3, 4.4, 4.3, 4.2, 4.1]
#Call this function every 0.5 seconds with the updated cell voltages flagged_cells_result=flag_cells (all_cell_voltages)
#The result will be a list of indices where cells have more than a 2% difference print (“Flagged cells:”, flagged_cells_result)
Calculate the rate of voltage change (dV/dt) using the following algorithm:
1. Measure Voltage:
   Record the battery cell voltage at regular intervals.
2. Calculate Voltage Change:
   Subtract the previous voltage reading from the current one to find the change in voltage.
3. Measure Time:
   Record the time interval between voltage measurements.
4. Calculate Rate of Voltage Change:
   Divide the voltage change by the time interval: ΔVΔt.
5. Set Threshold Ratio:
   Define a threshold ratio that indicates an abnormal rate of voltage change.
6. Flagging Condition:
   If the calculated rate of voltage change exceeds the threshold ratio, flag the cell as potentially problematic.
Adjust the threshold ratio based on application specific requirements and characteristics of the battery cells. This algorithm helps identify abnormal voltage changes that may indicate issues with the cell.
function flagCell(voltageReading, previous Voltage, timeInterval, thresholdRatio):
   voltageChange=voltageReading−previous Voltage
   rateOfVoltageChange=voltageChange/timeInterval
   if rateOfVoltageChange>thresholdRatio:
      return “Cell Flagged”
   else:
      return “Normal”
#Example usage:
cellStatus=flagCell(currentVoltage, previous Voltage, deltaTime, thresholdRatio)

### Example 2

This exemplary algorithm will include a comparison of electrolyte consumption between cells and/or as well as a comparison of electrolyte consumption to overall historical data to determine when over consumption is happening as an indicator for thermal run-aways. The following is what portions of the above described code can look like.
def compare_water_consumption(current_consumption, historical_data, threshold, max_difference):
   #Calculate the average historical water consumption avg_historical_consumption=sum(historical_data)/len(historical_data)
   #Calculate the difference between current consumption and historical average difference=current_consumption−avg_historical_consumption
   #Calculate the percentage difference between current consumption and historical average
   percentage_difference=abs((difference/avg_historical_consumption)*100)
   #Compare the percentage difference to the threshold
   if percentage_difference>threshold:
      return “Battery cell is potentially deteriorating”
   else:
      if percentage_difference>max_difference:
         return “Alarm: High variation in water consumption between cells”
      else:
         return “Battery cell is functioning normally”
#Example usage:
current_consumption=50 #Example current water consumption value
historical_data=[40, 45, 42, 38, 41] #Example historical water consumption data
threshold=5 #Example threshold value
max_difference=20 #Maximum allo

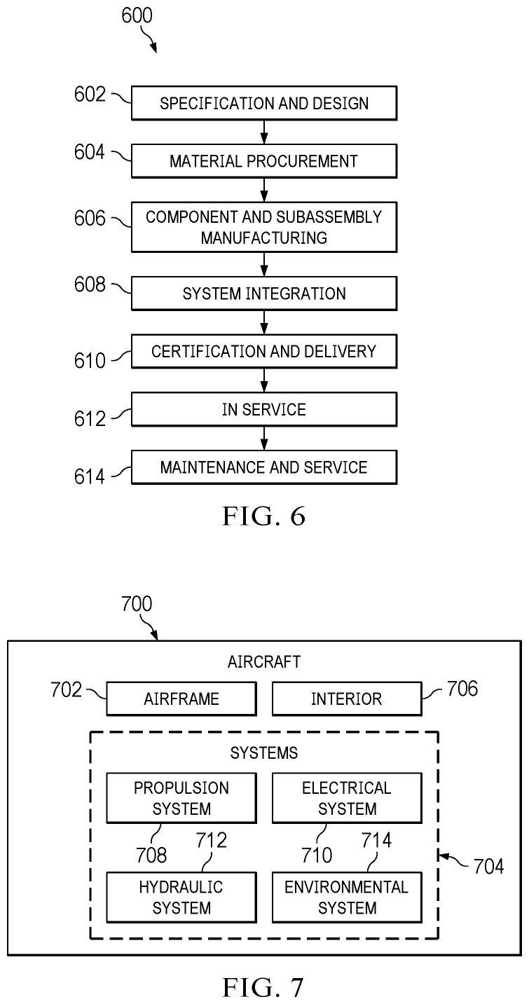

Illustrative embodiments of the present disclosure may be described in the context of aircraft manufacturing and service method 600 as shown in FIG. 6 and aircraft 700 as shown in FIG. 7. Turning first to FIG. 6, an illustration of an aircraft manufacturing and service method in the form of a block diagram is depicted in accordance with an illustrative embodiment. During pre-production, aircraft manufacturing and service method 600 may include specification and design 602 of aircraft 700 in FIG. 7 and material procurement 604.

During production, component and subassembly manufacturing 606 and system integration 608 of aircraft 700 takes place. Thereafter, aircraft 700 may go through certification and delivery 610 in order to be placed in service 612. While in service 612 by a customer, aircraft 700 is scheduled for routine maintenance and service 614, which may include modification, reconfiguration, refurbishment, or other maintenance and service.

Each of the processes of aircraft manufacturing and service method 600 may be performed or carried out by a system integrator, a third party, and/or an operator. In these examples, the operator may be a customer. For the purposes of this description, a system integrator may include, without limitation, any number of aircraft manufacturers and major-system subcontractors; a third party may include, without limitation, any number of vendors, subcontractors, and suppliers; and an operator may be an airline, a leasing company, a military entity, a service organization, and so on.

With reference now to FIG. 7, an illustration of an aircraft in a form of a block diagram is depicted in which an illustrative embodiment may be implemented. In this example, aircraft 700 is produced by aircraft manufacturing and service method 600 of FIG. 6 and may include airframe 702 with plurality of systems 704 and interior 706. Examples of systems 704 include one or more of propulsion system 708, electrical system 710, hydraulic system 712, and environmental system 714. Any number of other systems may be included.

Apparatuses and methods embodied herein may be employed during at least one of the stages of aircraft manufacturing and service method 600. One or more illustrative embodiments may be manufactured or used during at least one of component and subassembly manufacturing 606, system integration 608, in service 612, or maintenance and service 614 of FIG. 6.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A method of thermal run-away monitoring of a battery cell, comprising:
charging the battery cell;
measuring concurrently a state of charge of the battery cell, and at least one of voltage and electrolyte consumption while charging the battery cell;
recording a set of data for the battery cell, each member of the set of data comprising the state of charge of the battery cell, and at least one of voltage and electrolyte consumption;
comparing the set of data for the battery cell to a historical database of measurements from other battery cells characteristic of a type associated with the battery cell; and
predicting a probability of thermal run-away of the battery cell based on comparison of set of data for the battery cell to the historical database of measurements from other battery cells characteristic of the type associated with the battery cell.

2. The method of claim 1, further comprising removing the battery cell from a battery in response to the probability being greater than a predetermined threshold.

3. The method of claim 2, further comprising replacing the battery cell with another battery cell.

4. The method of claim 1, wherein a voltage is measured between an anode of the battery cell and a cathode of the battery cell, and wherein the voltage is measured a plurality of times.

5. The method of claim 4, wherein the voltage is measured at least 3 times.

6. The method of claim 5, wherein the at least 3 times are substantially equally spaced apart from one another.

7. The method of claim 1, wherein electrolyte consumption is measured, and wherein the electrolyte consumption is measured a plurality of times.

8. The method of claim 7, wherein the electrolyte consumption is measured at least 3 times.

9. The method of claim 8, wherein the at least 3 times are substantially equally spaced apart from one another.

10. An aircraft battery comprising a battery cell monitored using the method of claim 1.

11. An apparatus for thermal run-away monitoring of a battery cell, comprising:
a sensor system measuring concurrently a state of charge of the battery cell; and at least one of voltage and electrolyte consumption;
a memory recording a set of data for the battery cell, each member of the set of data comprising at least one of voltage and electrolyte consumption and the state of charge of the battery cell;
a pattern recognition system comparing the set of data for the battery cell to a historical database of measurements from other battery cells characteristic of a type associated with the battery cell; and
a prediction system predicting a probability of thermal run-away of the battery cell based on comparison of the set of data for the battery cell to the historical database of measurements from other battery cells characteristic of the type associated with the battery cell.

12. The apparatus of claim 11, wherein the sensor is configured to measure a voltage between an anode of the battery cell and a cathode of the battery cell, wherein the voltage is measured at a plurality of states of charge.

13. The apparatus of claim 12, wherein the sensor is configured to measure a temperature proximate the battery cell.

14. The apparatus of claim 11, wherein the sensor is configured to measure an electrolyte consumption, wherein the electrolyte consumption is measured at a plurality of states of charge.

15. The apparatus of claim 14, wherein the sensor comprises a non-contact electrolyte level sensor.

16. The apparatus of claim 15, wherein the non-contact electrolyte level sensor comprises at least one of a sonar sensor and an optical sensor.

17. The apparatus of claim 11, further comprising a gantry configured to remove the battery cell from a battery and replace the battery cell with another battery cell.

18. The apparatus of claim 11, further comprising a control panel.

19. An aircraft battery servicing machine comprising the apparatus of claim 11.

20. A method of thermal run-away monitoring of a battery cell, comprising:
charging the battery cell;
measuring concurrently at least one of voltage and electrolyte consumption, and a state of charge while charging the battery cell;
recording a set of data for the battery cell, each member of the set of data comprising at least one of voltage and electrolyte consumption, and the state of charge of the battery cell;
comparing the set of data for the battery cell to a historical database of measurements from other battery cells characteristic of a type associated with the battery cell;
predicting a probability of thermal run-away of the battery cell based on comparison of set of data for the battery cell to the historical database of measurements from other battery cells characteristic of the type associated with the battery cell;
removing the battery cell from a battery in response to the probability being greater than a predetermined threshold; and
replacing the battery cell with another battery cell.
